(19) United States
(12) Patent Application Publication
(10) Pub. No.: US 2006/0049418 A1
(43) Pub. Date: Mar. 9, 2006

(54) Epitaxial structure and fabrication method of nitride semiconductor device

(76) Inventors: Tzi-Chi Wen, Tainan City (TW); Ru-Chin Tu, Tainan City (TW); Cheng-Tsang Yu, Wufong Township (TW); Liang-Wen Wu, Banciao City (TW); Fen-Ren Chien, Yonghe City (TW)

Correspondence Address: SUPREME PATENT SERVICES, P.O. BOX 2339, SARATOGA, CA, 95070-0339, US

(21) Appl. No.: 10/934,857

(22) Filed: Sep. 3, 2004

(51) Int. Cl. H01L 33/00

(52) U.S. Cl. 257/98; 257/103; 257/93; 257/91

(57) ABSTRACT

A structure and a fabrication method for a nitride semiconductor device are provided so that the device has a lower defect density resulted from incompatible lattice constants between its constituent layers. The nitride semiconductor device contains a substrate, at least a first intermediate layer made of aluminum-gallium-indium-nitride (Al_{1-x-y}GaₓIn_{y}N) at least a second intermediate layer made of silicon-nitride (SiᵢNⱼ) or magnesium-nitride (MgₘNₙ), and a nitride epitaxial layer. The second intermediate layer is used to form a mask so that the subsequent epitaxial growth would have a smaller defect density and a better epitaxial quality.

### BACKGROUND OF THE INVENTION

1. Field of the Invention

The present invention relates to the nitride semiconductor device, and in particular to the epitaxial structure and fabrication method of the nitride semiconductor device.

2. The Prior Arts

According to prior arts, a conventional nitride semiconductor device such as a gallium-nitride (GaN) based light emitting diode (LED) has an epitaxial layer formed on top of a buffer layer, which in turn is formed on top of a substrate. Usually, the buffer layer within these conventional nitride semiconductor devices is formed by depositing aluminum-gallium-nitride (AlₓGa₁₋ₓN, 1≧x≧0) or indium-gallium-nitride (In_{y}Ga_{1-y}N, 1≧y≧0) under a low temperature (200-900° C.). The nitride epitaxial layer is then formed under a high temperature on the buffer layer. However, there is a huge difference between the substrate and the nitride epitaxial layer in terms of their lattice constants. This huge difference in the lattice structure causes the nitride epitaxial layer subsequently formed to have a defect density more than 10¹⁰/cm³. The nitride semiconductor device such as a GaN-based LED as fabricated has a poor resilience to electrostatic discharge, a short operation life, and inferior device characteristics.

Accordingly, the present invention is directed to overcome the foregoing disadvantages of conventional nitride semiconductor devices according to prior arts.

### SUMMARY OF THE INVENTION

The present invention provides a structure and a fabrication method for a nitride semiconductor device so that the limitations and disadvantages from the prior arts can be obviated practically.

The present invention utilizes appropriate intermediate layers to replace the conventional buffer layer. With the present invention, the nitride epitaxial layer is deposited on top of an intermediate layer made of either silicon-nitride (SiᵢNⱼ, i, j≧0) or magnesium-nitride (MgₘNₙ, m, n≧0), which in turn is formed on top of another intermediate layer made of aluminum-gallium-indium-nitride (Al_{1-x-y}GaₓIn_{y}N x, y≧0, 1≧x+y≧0). The defect density of the nitride epitaxial layer can be reduced to below 10¹⁰/cm³ within this structure. Both intermediate layers are formed by the metalorganic chemical vapor deposition (MOCVD) technique. For the intermediate layer made of SiᵢNⱼ (i, j≧0) or MgₘNₙ (m, n≧0), ammonia (NH₃) and silane (SiH₄), or NH₃ and disilane (Si₂H₆) are used to grow the SiᵢNⱼ (i, j≧0) during the MOCVD process. On the other hand, NH₃ and cyclopenta-dienyl-magnesium (CP₂Mg) are used to grow MgₘNₙ (m, n≧0) during the MOCVD process.

The present invention's reduction of the defect density of the nitride epitaxial layer lies in the phenomenon that, when the SiᵢNⱼ (i, j≧0) or MgₘNₙ (m, n≧0) intermediate layer is deposited on the A_{1-x-y}GaₓIn_{y}N (x, y≧0, 1≧x+y≧0) intermediate layer, the material SiᵢNⱼ or MgₘNₙ forms a mask having a random, clustered pattern. The nitride epitaxial layer subsequently deposited grows from the exposed Al_{1-x-y}GaₓIn_{y}N (x, y≧0, 1≧x+y≧0) intermediate layer not covered by the SiᵢNⱼ (i, j≧0) or MgₘNₙ (m, n≧0) mask, and then overflowed to the top of the mask, instead of directly from the top of the mask. A nitride epitaxial layer with lower defect density is thereby formed.

The foregoing and other objects, features, aspects and advantages of the present invention will become better understood from a careful reading of a detailed description provided herein below with appropriate reference to the accompanying drawings.

### BRIEF DESCRIPTION OF THE DRAWINGS

FIG. 1 is a schematic diagram showing the structure of the nitride semiconductor device according to the first embodiment of present invention.

FIG. 2 is a flow diagram showing the processing steps for forming the nitride semiconductor device as depicted in FIG. 1.

FIG. 3 is a schematic diagram showing the structure of the nitride semiconductor device according to the second embodiment of present invention.

FIG. 4 is a schematic diagram showing the structure of the nitride semiconductor device according to the third embodiment of present invention.

FIG. 5 is a flow diagram showing the processing steps for forming the nitride semiconductor device as depicted in FIG. 4.

FIG. 6 is a schematic diagram showing the structure of the nitride semiconductor device according to the fourth embodiment of present invention.

### DETAILED DESCRIPTION OF THE PREFERRED EMBODIMENTS

In the following, detailed description along with the accompanied drawings is given to better explain preferred embodiments of the present invention. Please be noted that, in the accompanied drawings, some parts are not drawn to scale or are somewhat exaggerated, so that people skilled in the art can better understand the principles of the present invention.

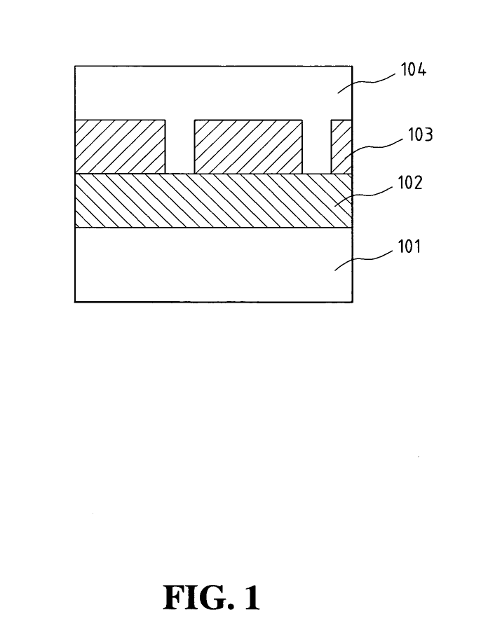

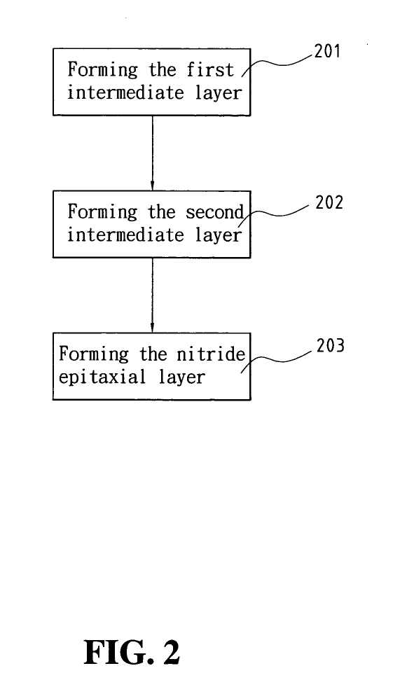

FIG. 1 is a schematic diagram showing the structure of the nitride semiconductor device according to the first embodiment of present invention. FIG. 2 is a flow diagram showing the processing steps for forming the nitride semiconductor device as depicted in FIG. 1. As shown in FIG. 1, the nitride semiconductor device is formed by stacking a first intermediate layer 102, a second intermediate layer 103, and a nitride epitaxial layer 104, sequentially in this order from bottom to top on a substrate 101. The second intermediate layer 103, when deposited, would form a mask having a random, clustered pattern on the first intermediate layer 102. The nitride epitaxial layer 104 subsequent deposited then grows from the exposed first intermediate layer 102 not covered by the mask of the second intermediate layer 103, and overflows to cover the top of the mask of the second intermediate layer 103. The processing steps, as shown in FIG. 2, include: on the substrate 101, forming the first intermediate layer 102 made of Al_{1-x-y}GaₓIn_{y}N (x, y≧0, 1≧x+y≧0) having a thickness between 5 Å and 10 Å by using a MOCVD process under a temperature between 200° C. and 1000° C. (step 201); forming the second intermediate layer 103 made of SiᵢNⱼ (i, j≧0) having a thickness between 5 Å and 100 Å by using NH₃ and SiH₄ (or using NH₃ and Si₂H₆) in a MOCVD process under a temperature between 200° C. and 1000° C. on the first intermediate layer 102 (step 202); and forming a nitride epitaxial layer 104 by using a MOCVD process under a temperature between 700° C. and 1100° C. on the second intermediate layer 103 (step 203).

The foregoing second intermediate layer 103 can also be made of MgₘNₙ (m, n≧0) by using NH₃ and CP₂Mg in the MOCVD process.

When the second intermediate layer 103 is made of SiᵢNⱼ (i, j≧0) or MgₘNₙ (m, n≧0), the material SiᵢNⱼ or MgₘNₙ forms a mask having a random, clustered pattern on the first intermediate layer 102. The nitride epitaxial layer 104 subsequently deposited then grows from the exposed first intermediate layer 102 not covered by the SiᵢNⱼ or MgₘNₙ mask, and overflows to cover the top of the second intermediate layer 103, instead of directly from the top of the second intermediate layer 103. The nitride epitaxial layer 104 therefore has a lower defect density.

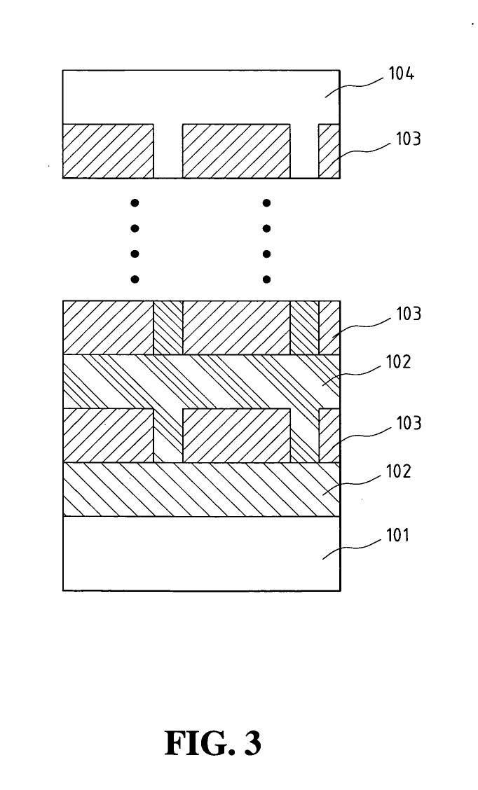

FIG. 3 is a schematic diagram showing the structure of the nitride semiconductor device according to the second embodiment of present invention. As shown in FIG. 3, the nitride semiconductor device contains multiple first and second intermediate layers 102 and 103 stacked alternately upon each other between the substrate 101 and the nitride epitaxial layer 104. More specifically, on the substrate 101, the steps 201 and 202 as depicted in FIG. 2 are performed in sequence to form the first pair of the first and second intermediate layers 102 and 103. But before the step 203 is performed, the steps 201 and 202 are repeated at least once so that additional pairs of the first and second intermediate layers 102 and 103 are formed and stacked upon one another. Each of the first intermediate layers 102 is made of Al_{1-p-q}GaₚIn_{q}N (p, q≧0, 1≧p+q≧0) with a specific composition, and has a thickness between 5 Å and 10 Å. Similarly, each of the second intermediate layers 103 is made of SiₐN_{b} (a, b≧0) or Mg_{c}N_{d} (c, d≧0) with a specific composition, and has a thickness between 5 Å and 100 Å. At last, the step 203 is performed to form the nitride epitaxial layer 104 on top of the topmost second intermediate layer 103.

As in the first embodiment of the present invention, the SiₐN_{b} or Mg_{c}N_{d} of each of the second intermediate layer 103 forms a mask having a random, clustered pattern on the underlying first intermediate layer 102. The next first intermediate layer 102 or the nitride epitaxial layer 104 subsequent deposited then grows from the exposed, underlying first intermediate layer 102 not covered by the SiₐN_{b} or Mg_{c}N_{d} mask, and then overflows to cover the top of the underlying second intermediate layer 103. The next first intermediate layer 102 or the nitride epitaxial layer 104 therefore has a lower defect density.

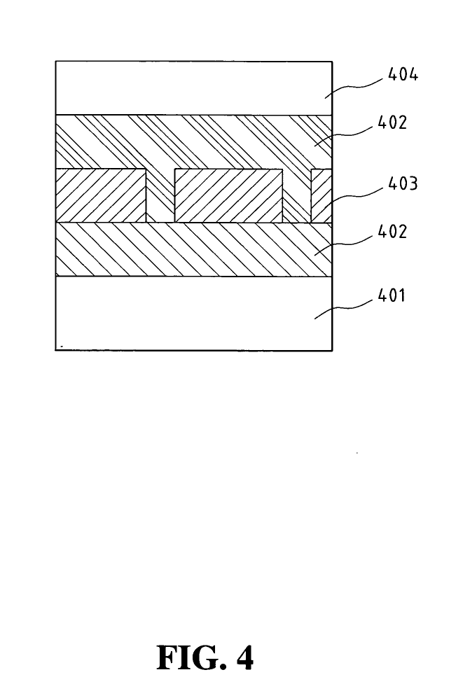

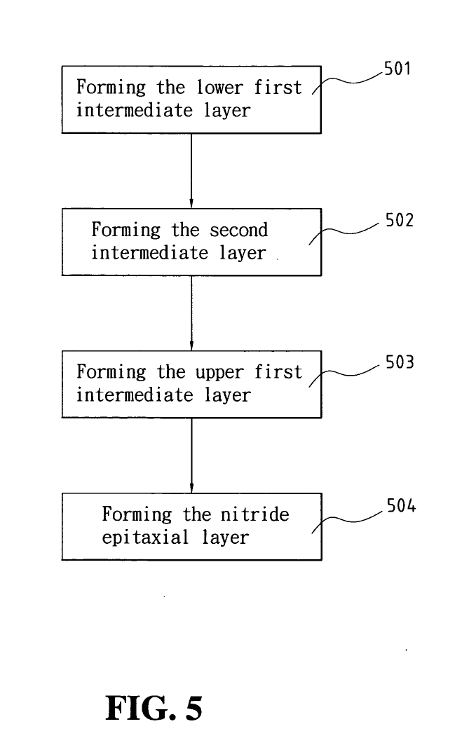

FIG. 4 is a schematic diagram showing the structure of the nitride semiconductor device according to the third embodiment of present invention. FIG. 5 is a flow diagram showing the processing steps for forming the nitride semiconductor device as depicted in FIG. 4. As shown in FIG. 4, the nitride semiconductor device is formed by stacking a lower first intermediate layer 402, a second intermediate layer 403, an upper first intermediate layer 402, and a nitride epitaxial layer 404, sequentially in this order from bottom to top on a substrate 401. The second intermediate layer 403, when deposited, would form a mask having a random, clustered pattern on the lower first intermediate layer 402. The upper first intermediate layer 402 subsequent deposited then grows from the exposed, lower first intermediate layer 402, and overflows to cover the top of the mask of the second intermediate layer 403. The upper first intermediate layer 402 is added to enhance the epitaxial quality of the nitride epitaxial layer 404. The processing steps, as shown in FIG. 5, include: on the substrate 101, forming the lower first intermediate layer 402 made of Al₁₋ₛ₋ₜGaₛInₜN (s, t≧0, 1≧s+t≧0) having a thickness between 5 Å and 10 Å by using a MOCVD process under a temperature between 200° C. and 1000° C. (step 501); forming the second intermediate layer 403 made of SiₑN_{f} (e, f≧0) having a thickness between 5 Å and 100 Å by using NH₃ and SiH₄ (or using NH₃ and Si₂H₆) in a MOCVD process under a temperature between 200° C. and 1000° C. on the first intermediate layer 402 (step 502); forming the upper first intermediate layer 402 made of Al₁₋ᵤ₋ᵥGaᵤInᵥN (u, v≧0, 1≧u+v≧0) having a thickness between 5 Å and 10 Å by using a MOCVD process under a temperature between 200° C. and 1000° C. on the second intermediate layer 403 (step 503); and forming a nitride epitaxial layer 404 through a common epitaxial technique under a temperature between 700° C. and 1100° C. on the upper first intermediate layer 402 (step 504).

The foregoing second intermediate layer 403 can also be made of Mg_{g}Nₕ (g, h≧0) by using NH₃ and CP₂Mg in the MOCVD process.

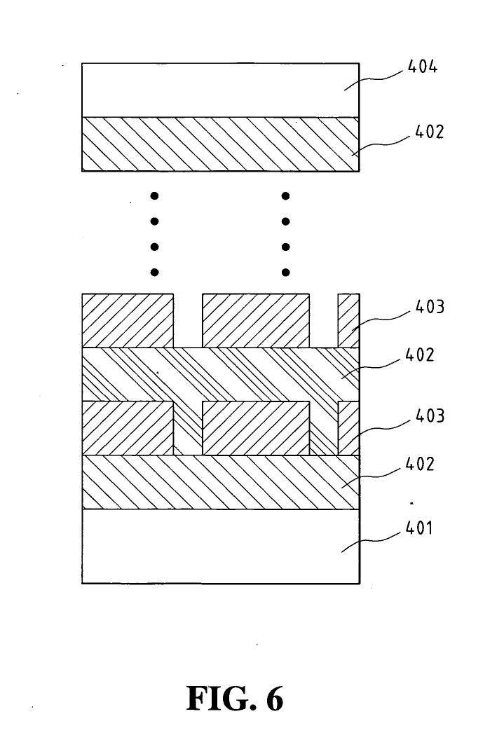

FIG. 6 is a schematic diagram showing the structure of the nitride semiconductor device according to the fourth embodiment of present invention. As shown in FIG. 6, the nitride semiconductor device contains multiple first and second intermediate layers 402 and 403 stacked alternately upon each other between the substrate 401 and the nitride epitaxial layer 404. More specifically, on the substrate 401, the steps 501, 502, and 503 as depicted in FIG. 5 are performed in sequence to form the lower first intermediate layer 402, the second intermediate layer 403, and the upper first intermediate layers 402. But before the step 504 is performed, the steps 502 and 503 are repeated so that additional pairs of the second and first intermediate layers 403 and 402 are formed and stacked upon one another, and the topmost layer is the first intermediate layer 402. Each of the first intermediate layers 402 is made of Al_{1-w-z}Ga_{w}In_{z}N (w, z≧0, 1≧w+z≧0) with a specific composition and has a thickness between 5 Å and 10 Å. Similarly, each of the second intermediate layers 403 is made of SiₖN₁ (k, 1≧0) or MgₛNₜ (s, t≧0) with a specific composition, and has a thickness between 5 Å and 100 Å. At last, the step 504 is performed to form the nitride epitaxial layer 404 on top of the topmost first intermediate layer 402.

In the third embodiment and the fourth embodiments of the present invention, the SiₖN₁ (k, 1≧0) or MgₛNₜ (s, t≧0) of each of the second intermediate layer 403 forms a mask having a random, clustered pattern on the underlying first intermediate layer 402. The next intermediate layer 402 subsequent deposited then grows from the exposed, underlying first intermediate layer 402 not covered by the SiₖN₁ or MgₛNₜ mask, and overflows to cover the top of the second intermediate layer 403. The next first intermediate layer 402 therefore has a lower defect density. Accordingly, the nitride epitaxial layer 404 formed on the topmost first intermediate layer 402 also has a lower defect density.

Although the present invention has been described with reference to the preferred embodiments, it will be understood that the invention is not limited to the details described thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A nitride semiconductor device, comprising:
a substrate;
a first intermediate layer made of Al_{1-x-y}GaₓIn_{y}N (x, y≧0, 1≧x+y≧0) having an appropriate thickness on top of said substrate;
a second intermediate layer made of SiᵢNⱼ (i, j≧0) forming a mask having a random, clustered pattern with an appropriate thickness on top of said first intermediate layer; and
a nitride epitaxial layer growing from said exposed, first intermediate layer not covered by said second intermediate layer and overflowing to cover said second intermediate layer.

2. The nitride semiconductor device as claimed in claim 1, wherein said first intermediate layer and said second intermediate layer alternate with each other so that there are a plurality of pairs of said first intermediate layer and said second intermediate layer with a layer of said first intermediate layer immediately above said substrate and a layer of said second intermediate layer immediately beneath said nitride epitaxial layer.

3. The nitride semiconductor device as claimed in claim 1, wherein said second intermediate layer is made of MgₘNₙ (m, n≧0).

4. The nitride semiconductor device as claimed in claim 1, wherein said first intermediate layer has a thickness between 5 Å and 10 Å.

5. The nitride semiconductor device as claimed in claim 1, wherein said second intermediate layer has a thickness between 5 Å and 100 Å.

6. A method for fabricating a nitride semiconductor device, comprising the following steps:
(a) preparing a substrate;
(b) forming a first intermediate layer made of Al_{1-x-y}GaₓIn_{y}N (x, y≧0, 1≧x+y≧0) having an appropriate thickness by using a MOCVD process under an appropriate temperature;
(c) forming a second intermediate layer made of SiᵢNⱼ (i, j≧0) having an appropriate thickness on said first intermediate layer by using NH₃ and a material selected from the group consisting of SiH₄ and Si₂H₆ in a MOCVD process under an appropriate temperature; and
(d) forming a nitride epitaxial layer on said second intermediate layer by using a MOCVD process under an appropriate temperature.

7. The method for fabricating a nitride semiconductor device as claimed in claim 6, wherein an additional step is repeated at least once after said steps (c) and before said step (d), so that there are a plurality of pairs of said first intermediate layer and said second intermediate layer with a layer of said first intermediate layer immediately above said substrate and a layer of said second intermediate layer immediately beneath said nitride epitaxial layer, which comprises the steps of:
(a′) forming another first intermediate layer made of Al_{1-p-q}GaₚIn_{q}N (p, q≧0, 1≧p+q≧0) having an appropriate thickness on an underlying said second intermediate layer by using a MOCVD process under an appropriate temperature; and
(b′) forming another second intermediate layer made of SiₐN_{b} (a, b≧0) having an appropriate thickness on said first intermediate layer formed in step (a′) by using NH₃ and a material selected from the group consisting of SiH₄ and Si₂H₆ in a MOCVD process under an appropriate temperature.

8. The method for fabricating a nitride semiconductor device as claimed in claim 6, wherein said second intermediate layer forms a mask having a random, clustered pattern on an underlying, said first intermediate layer so that said nitride epitaxial layer subsequently deposited grows from said underlying, first intermediate layer not covered by said second intermediate layer and overflows to cover said second intermediate layer.

9. The method for fabricating a nitride semiconductor device as claimed in claim 6, wherein said first intermediate layer has a growing temperature between 200° C. and 1000° C.

10. The method for fabricating a nitride semiconductor device as claimed in claim 6, wherein said second intermediate layer has a growing temperature between 200° C. and 1000° C.

11. The method for fabricating a nitride semiconductor device as claimed in claim 6, wherein said nitride epitaxial layer has a growing temperature between 700° C. and 1100° C.

12. The method for fabricating a nitride semiconductor device as claimed in claim 6, wherein said second intermediate layer is made of Mg_{c}N_{d} (c, d≧0) by using NH₃ and CP₂Mg in a MOCVD process.

13. The method for fabricating a nitride semiconductor device as claimed in claim 6, wherein said first intermediate layer has a thickness between 5 Å and 10 Å.

14. The method for fabricating a nitride semiconductor device as claimed in claim 6, wherein said second intermediate layer has a thickness between 5 Å and 100 Å.

15. A nitride semiconductor device, comprising:
a substrate;
a lower first intermediate layer made of Al₁₋ₛ₋ₜGaₛInₜN (s, t≧0, 1≧s+t≧0) having an appropriate thickness on top of said substrate;
a second intermediate layer made of SiₑN_{f} (e, f≧0) forming a mask having a random, clustered pattern with an appropriate thickness on top of said first intermediate layer;
an upper first intermediate layer having an appropriate thickness made of Al₁₋ᵤ₋ᵥGaᵤInᵥN (u, v≧0, 1≧u+v≧0) growing from said lower first intermediate layer not covered by said second intermediate layer and overflowing to cover said second intermediate layer; and
a nitride epitaxial layer on top of said upper first intermediate layer.

16. The nitride semiconductor device as claimed in claim 15, wherein said second intermediate layer and said first intermediate layer alternate with each other so that there are a plurality of pairs of said second intermediate layer and said first intermediate layer with a layer of said first intermediate layer immediately above said substrate and a layer of said first intermediate layer immediately beneath said nitride epitaxial layer.

17. The nitride semiconductor device as claimed in claim 15, wherein said second intermediate layer is made of Mg_{g}Nₕ (g, h≧0).

18. The nitride semiconductor device as claimed in claim 15, wherein said first intermediate layer has a thickness between 5 Å and 100 Å.

19. The nitride semiconductor device as claimed in claim 15, wherein said second intermediate layer has a thickness between 5 Å and 100 Å.

20. A method for fabricating a nitride semiconductor device, comprising the following steps:
(a) preparing a substrate;
(b) forming a lower first intermediate layer made of Al₁₋ₛ₋ₜGaₛInₜN (s, t≧0, 1≧s+t≧0) having an appropriate thickness on a substrate by using a MOCVD process under an appropriate temperature;
(c) forming a second intermediate layer made of SiₑN_{f} (e, f≧0) having an appropriate thickness on said lower first intermediate layer by using NH₃ and a material selected from the group consisting of SiH₄ and Si₂H₆ in a MOCVD process under an appropriate temperature;
(d) forming an upper first intermediate layer made of Al₁₋ᵤ₋ᵥGaᵤInᵥN (u, v≧0, 1≧u+v≧0) having an appropriate thickness on said second intermediate layer by using a MOCVD process under an appropriate temperature; and
(e) forming a nitride epitaxial layer on said upper first intermediate layer by using a MOCVD process under an appropriate temperature.

21. The method for fabricating a nitride semiconductor device as claimed in claim 20, wherein an additional step is repeated at least once after said steps (d) and before said step (e), so that there are a plurality of pairs of said second intermediate layer and said first intermediate layer with a layer of said first intermediate layer immediately beneath said nitride epitaxial layer, which comprises the steps of:
(a′) forming another second intermediate layer made of SiₖN₁ (k, 1≧0) having an appropriate thickness on a underlying said upper first intermediate layer by using NH₃ and a material selected from the group consisting of SiH₄ and Si₂H₆ in a MOCVD process under an appropriate temperature; and
(b′) forming another upper first intermediate layer made of A_{1-w-z}Ga_{w}In_{z}N (w,z≧0, 1≧w+z≧0) having an appropriate thickness on said second intermediate layer formed in step (a′) by using a MOCVD process under an appropriate temperature.

22. The method for fabricating a nitride semiconductor device as claimed in claim 20, wherein said second intermediate layer forms a mask having a random, clustered pattern on an underlying first intermediate layer so that a next first intermediate layer subsequently deposited grows from said previous, underlying first intermediate layer not covered by said second intermediate layer and overflows to cover said second intermediate layer.

23. The method for fabricating a nitride semiconductor device as claimed in claim 20, wherein each of said first intermediate layer has a growing temperature between 200° C. and 1000° C.

24. The method for fabricating a nitride semiconductor device as claimed in claim 20, wherein said second intermediate layer has a growing temperature between 200° C. and 1000° C.

25. The method for fabricating a nitride semiconductor device as claimed in claim 20, wherein said nitride epitaxial layer has a growing temperature between 700° C. and 1100° C.

26. The method for fabricating a nitride semiconductor device as claimed in claim 20, wherein said second intermediate layer is made of MgₛNₜ (s, t≧0) by using NH₃ and CP₂Mg in a MOCVD process.

27. The method for fabricating a nitride semiconductor device as claimed in claim 20, wherein each of said first intermediate layers has a thickness between 5 Å and 10 Å.

28. The method for fabricating a nitride semiconductor device as claimed in claim 20, wherein said second intermediate layer has a thickness between 5 Å and 100 Å.
